(19) United States
(12) Patent Application Publication
(10) Pub. No.: US 2023/0258686 A1
(43) Pub. Date: Aug. 17, 2023

(54) MEMS SENSOR

(71) Applicant: ROHM CO., LTD., Kyoto (JP)

(72) Inventor: Daisuke KAMINISHI, Kyoto (JP)

(73) Assignee: ROHM CO., LTD., Kyoto (JP)

(21) Appl. No.: 18/091,482

(22) Filed: Dec. 30, 2022

(30) Foreign Application Priority Data
Feb. 17, 2022 (JP) 2022-023202

(51) Int. Cl. G01P 15/125; G01P 15/18; B81B 7/02

(52) U.S. Cl. CPC G01P 15/125; G01P 15/18; B81B 7/02; B81B 2201/0235

(57) ABSTRACT

A MEMS sensor includes: a pair of movable electrodes arranged to be parallel to each other with a space portion interposed between the pair of movable electrodes above a cavity portion provided in a substrate; and a fixed electrode arranged to be parallel to the pair of movable electrodes with a groove portion interposed between the fixed electrode and the pair of movable electrodes on an opposite side of the space portion with respect to the pair of movable electrodes, wherein the space portion includes a central portion having a first space width and end portions having a second space width, and wherein the first space width is shorter than the second space width.

### CROSS-REFERENCE TO RELATED APPLICATION

This application is based upon and claims the benefit of priority from Japanese Patent Application No. 2022-023202, filed on Feb. 17, 2022, the entire contents of which are incorporated herein by reference.

### TECHNICAL FIELD

The present disclosure relates to a MEMS sensor, and more particularly to capacitive acceleration sensors using a MEMS structure.

### BACKGROUND

There has been known a capacitive acceleration sensor in which a fixed electrode and a movable electrode are arranged to face each other and acceleration is detected by detecting a change in capacitance between the two electrodes. As such a capacitive acceleration sensor, there has been proposed a sensor using a MEMS (Micro Electro Mechanical System) structure in which a fixed electrode and a movable electrode are manufactured by processing a silicon substrate using a semiconductor microfabrication technique.

The capacitive acceleration sensor detects acceleration by detecting a change in capacitance between the fixed electrode and the movable electrode that is caused by a change in a position of the movable electrode with respect to the fixed electrode. Therefore, by narrowing a distance between the fixed electrode and the movable electrode to increase the capacitance, the sensitivity of the acceleration sensor can be improved.

On the other hand, however, in the MEMS structure, it is necessary to form a cavity portion by etching a lower portion of the fixed electrode or the movable electrode so as to be a structure in which the electrode floats from a semiconductor substrate. Therefore, when a gap between the fixed electrode and the movable electrode becomes narrow, it becomes difficult for an etchant to enter the semiconductor substrate from between the two electrodes, so that there was a problem in that it is difficult to form the electrodes.

### SUMMARY

Some embodiments of the present disclosure provide a high-sensitivity MEMS sensor which has a narrow gap between a fixed electrode and a movable electrode and which is easy to manufacture.

According to one embodiment of the present disclosure, a MEMS sensor includes: a pair of movable electrodes arranged to be parallel to each other with a space portion interposed between the pair of movable electrodes above a cavity portion provided in a substrate; and a fixed electrode arranged to be parallel to the pair of movable electrodes with a groove portion interposed between the fixed electrode and the pair of movable electrodes on an opposite side of the space portion with respect to the pair of movable electrodes, wherein the space portion includes a central portion having a first space width and end portions having a second space width, and wherein the first space width is shorter than the second space width.

According to another embodiment of the present disclosure, a MEMS sensor includes: a pair of movable electrodes arranged to be parallel to each other with a space portion interposed between the pair of movable electrodes above a cavity portion provided in the substrate; and a fixed electrode arranged to be parallel to the pair of movable electrodes with a groove portion interposed between the fixed electrode and the pair of movable electrodes on an opposite side of the space portion with respect to the pair of movable electrodes, wherein the pair of the movable electrodes includes finger portions on a side of the space portion, respectively, and wherein, when a groove width of the groove portion is 2.0 μm or more and 2.8 μm or less, a following formula (2) is satisfied:

0≤b/((Z1/2)+(Y+b)+X)<0.125 (2)

where Z1 is an interval between the finger portions, Y is a width of each of the pair of movable electrodes, b is a width of the finger portions, and X is the groove width.

According to another embodiment of the present disclosure, a MEMS sensor includes: a pair of movable electrodes arranged to be parallel to each other with a space portion interposed between the pair of movable electrodes above a cavity portion provided in a substrate; and a fixed electrode arranged to be parallel to the pair of movable electrodes with a groove portion interposed between the fixed electrode and the pair of movable electrodes on an opposite side of the space portion with respect to the pair of movable electrodes, wherein the pair of movable electrodes includes finger portions on a side of the space portion, and wherein, when a groove width of the groove portion is 1.5 μm or more and less than 2.0 μm, a following formula (3) is satisfied:

0.027≤b/((Z1/2)+(Y+b)+X)≤0.054 (3)

where Z1 is an interval between the finger portions, Y is a width of each of the pair of movable electrodes, b is a width of the finger portions, and X is the groove width.

### BRIEF DESCRIPTION OF DRAWINGS

The accompanying drawings, which are incorporated in and constitute a part of the specification, illustrate embodiments of the present disclosure.

FIG. 1 is a plan view of an acceleration sensor according to an embodiment of the present disclosure.

FIG. 2 is an enlarged view of region A in the acceleration sensor shown in FIG. 1.

FIG. 3A is a cross-sectional view showing a process of manufacturing an electrode of an acceleration sensor according to an embodiment of the present disclosure.

FIG. 3B is a cross-sectional view showing a process of manufacturing an electrode of an acceleration sensor according to an embodiment of the present disclosure.

FIG. 3C is a cross-sectional view showing a process of manufacturing an electrode of an acceleration sensor according to an embodiment of the present disclosure.

FIG. 3D is a cross-sectional view showing a process of manufacturing an electrode of an acceleration sensor according to an embodiment of the present disclosure.

FIG. 3E is a cross-sectional view showing a process of manufacturing an electrode of an acceleration sensor according to an embodiment of the present disclosure.

FIG. 3F is a cross-sectional view showing a process of manufacturing an electrode of an acceleration sensor according to an embodiment of the present disclosure.

FIG. 3G is a cross-sectional view showing a process of manufacturing an electrode of an acceleration sensor according to an embodiment of the present disclosure.

FIG. 4A is a plan view of an electrode structure of an acceleration sensor according to an embodiment of the present disclosure.

FIG. 4B is a schematic diagram of an electrode structure of an acceleration sensor according to an embodiment of the present disclosure.

FIG. 5 is a plan view of an electrode structure of an acceleration sensor according to an embodiment of the present disclosure.

FIG. 6 is a schematic diagram of an acceleration sensor when a size of a finger portion is changed.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

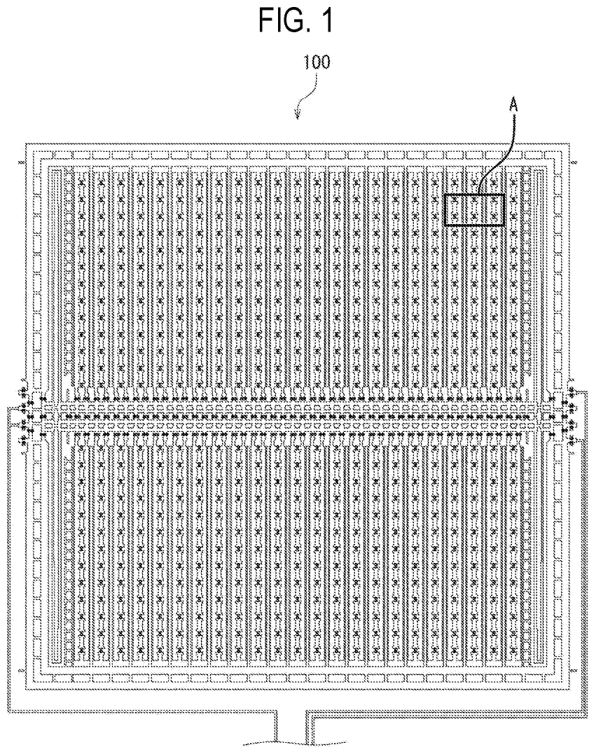

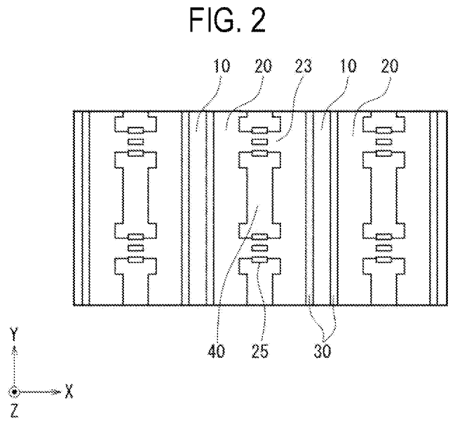

FIG. 1 is a plan view of a capacitive acceleration sensor having a MEMS structure according to an embodiment of the present disclosure, which is generally designated by “100,” and FIG. 2 is an enlarged view of region A in FIG. 1. In the acceleration sensor 100, movable electrodes 20 are installed in parallel on both sides of a fixed electrode 10 linearly extending in a Y-axis direction. The fixed electrode 10 and the movable electrode 20 extend in a stripe-like shape with a constant width, and a groove portion 30 is formed between the fixed electrode 10 and the movable electrode 20.

Two adjacent movable electrodes 20 are connected by a connecting portion 23, and an inside of the two adjacent movable electrodes 20 becomes a space portion 40. The two movable electrodes 20 are insulated from each other by an isolation joint (IJ) 25 provided at the center of the connecting portion 23.

The fixed electrode 10, the movable electrodes 20, and the connecting portion 23 having the isolation joint 25 are held in a floating state with respect to the silicon substrate above a cavity portion provided in the silicon substrate. Therefore, when the acceleration sensor 100 receives a constant acceleration, the gap between the fixed electrode 10 and the movable electrode 20 is changed. Accordingly, the capacitance between the two electrodes 10 and 20 is also changed. Acceleration can be detected by detecting the change in capacitance.

Since the fixed electrode 10 and the movable electrode 20 form a parallel-plate capacitor, the narrower the gap (distance in the X-axis direction) between the fixed electrode 10 and the movable electrode 20, the greater the capacitance, which makes it possible to improve the acceleration detection accuracy. Therefore, in the acceleration sensor 100 having the MEMS structure, the detection accuracy can be improved by narrowing the gap between the fixed electrode 10 and the movable electrode 20 through the use of a semiconductor microfabrication technique.

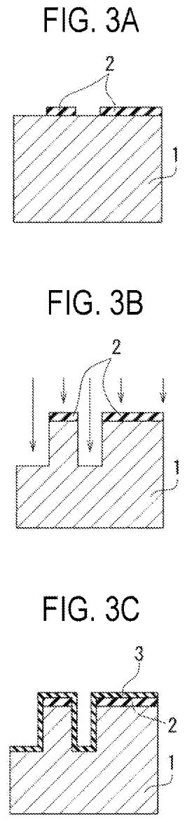

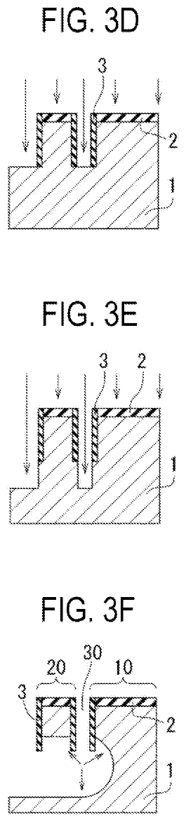

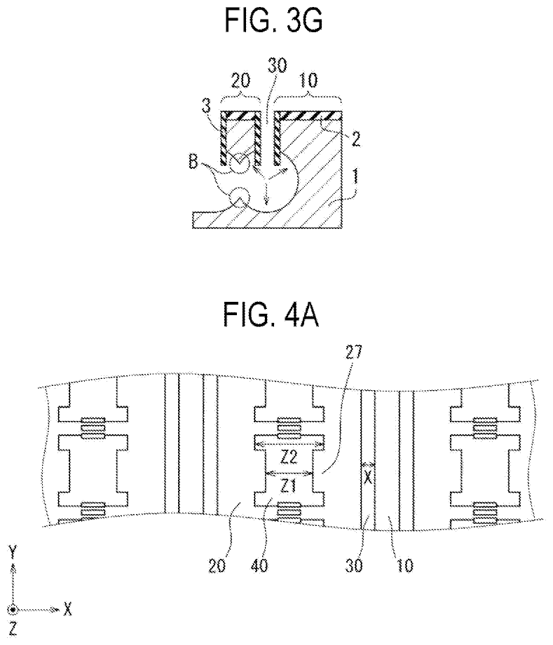

FIGS. 3A to 3G are schematic diagrams showing a process of manufacturing the electrode of the acceleration sensor 100 by using a semiconductor microfabrication technique. The electrode is manufactured through processes 1 to 6 below.

Process 1: As shown in FIG. 3A, a silicon oxide film 2 is formed on an entire surface of a silicon substrate 1 by thermal oxidation, and is then patterned by lithography. In FIG. 3A, the silicon oxide film 2 extends linearly with a constant width in a direction perpendicular to a plane of the drawing sheet.

Process 2: As shown in FIG. 3B, by reactive ion etching (RIE) using, for example, a mixed gas of SF₆ and C₄F₈, the silicon substrate 1 is etched using the silicon oxide film 2 as a mask and a groove portion is formed. The depth of the groove portion is, for example, 30 μm.

Process 3: As shown in FIG. 3C, a TEOS (tetra ethoxy silane) film 3 is formed on the entire surface of the silicon substrate 1 using a CVD method.

Process 4: As shown in FIG. 3D, the entire surface of the silicon substrate 1 is etched by sputtering using, for example, a CF-based gas and the TEOS film 3 is removed. As a result, the TEOS film 3 remains only on a sidewall of the groove portion formed on the silicon substrate 1.

Process 5: As shown in FIG. 3E, the silicon substrate 1 is additionally etched to deepen the groove portion. As in process 2, the additional etching is performed by RIE using a mixed gas of SF₆ and C₄F₈, and by using the silicon oxide film 2 as a mask. As a result, the depth of the groove portion is about 5 μm. Further, the TEOS film 3 remains on the side wall of the groove portion over a region from an upper end to a middle of the groove portion.

Process 6: As shown in FIG. 3F, the silicon substrate 1 is etched by plasma isotropic etching using, for example, an SF₆ gas, and by using the silicon oxide film 2 and the TEOS film 3 as an etching mask. As a result, the silicon substrate 1 is etched at a lower portion covered with the silicon oxide film 2 and the TEOS film 3 to thereby form a cavity portion, and an electrode structure floating from the silicon substrate 1 is formed. In this case, a left side is the movable electrode 20, a right side is the fixed electrode 10, and the groove portion 30 is formed therebetween.

However, when the gap between the movable electrode 20 and the fixed electrode 10 (the width of the groove portion 30) becomes narrow, it becomes difficult for the SF₆ gas to enter the groove portion 30 in the process 6. As a result, as shown in FIG. 3G, the etching below the electrode becomes insufficient, so that fragile protrusions as indicated by B (fragile structure) remain. Such protrusions are broken during the movement of the movable electrode 20, which causes a malfunction of the acceleration sensor. Further, if the width of the groove portion 30 becomes narrower and the isotropic etching becomes insufficient, a portion between the movable electrode 20 and the silicon substrate 1 is not completely etched, and the movable electrode 20 may not float (may not be released) from the silicon substrate 1.

Although not shown in FIG. 3G, such etching defects are also generated in the etching of the silicon substrate 1 under the fixed electrode 10. Thus, protrusions may remain in the vicinity of the fixed electrode 10, or the fixed electrode 10 may not float from the silicon substrate 1.

In the embodiment of the present disclosure, as shown in FIG. 2, even when the gap between the fixed electrode 10 and the movable electrode 20 (the width of the groove portion 30) is narrow, good etching as shown in FIG. 3F can be achieved by adjusting an amount of an etchant supplied from a space portion 40 between the two movable electrodes 20.

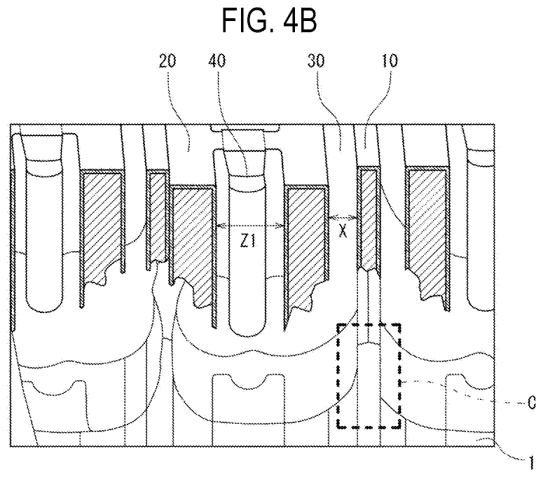

FIG. 4A is a plan view of an electrode structure of the acceleration sensor 100, and FIG. 4B is a schematic view of the electrode structure of the acceleration sensor 100 corresponding to FIG. 4A. In 4A, “10” denotes a fixed electrode, “20” denotes a movable electrode, “30” denotes a groove portion between the fixed electrode 10 and the movable electrode 20, and “40” denotes a space between the two movable electrodes 20. Further, “27” denotes a rectangular finger portion installed on the movable electrode 20.

As described above, if the gap between the fixed electrode 10 and the movable electrode 20, that is, the groove width X of the groove portion 30, is made small in order to increase the sensitivity of the acceleration sensor 100, an amount of an etchant (e.g., SF₆) that enters from the groove portion 30 and etches the silicon substrate 1 is reduced. On the other hand, since the gap between the two movable electrodes 20 (the width of the space portion) is sufficiently larger than the groove width X of the groove portion 30, the amount of the etchant entering from the space portion 40 and etching the silicon substrate 1 also increases. Therefore, if the groove width X of the groove portion 30 is reduced, the amount of the etchant supplied from the space portion 40 and the amount of the etchant supplied from the groove portion 30 are out of balance. As a result, for example, etching of a region C surrounded by the two groove portions 30 is insufficient and the fragile protrusions remain without being etched.

Therefore, in the embodiment of the present disclosure, the movable electrode 20 is provided with the finger portion 27 protruding toward the space portion 40 to narrow the first space width Z1 at a center of the space portion 40 and limit the amount of the etchant supplied from the space portion 40, whereby the balance with the amount of the etchant supplied from the groove portion 30 is adjusted so that good etching can be obtained. As shown in FIG. 4A, the space portion 40 includes a central portion having a first space width Z1 and end portions existing on both sides of the central portion and having a second space width Z2. The first space width Z1 is smaller than the second space width Z2.

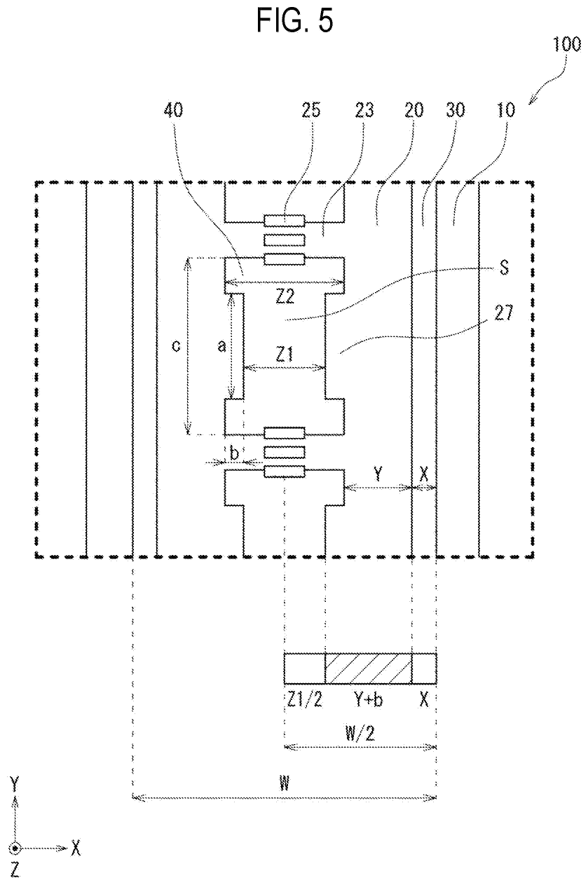

FIG. 5 is a plan view showing dimensions of the electrode structure of the acceleration sensor 100 of the present disclosure, and an etching explanatory diagram (lower right) for one half of a unit cell. In the acceleration sensor 100, the fixed electrode 10 and the movable electrode 20 extend in a stripe shape with a constant width in the Y-axis direction, and are arranged parallel to each other with the groove portion 30 having a groove width X interposed therebetween. The two adjacent movable electrodes 20 are connected by the connecting portion 23 and electrically insulated from each other by the isolation joint 25. The space portion 40 is formed by opening a portion surrounded by the two movable electrodes 20 and the connecting portion 23. The fixed electrode 10, the movable electrodes 20, and the connecting portion 23 having the isolation joint 25 are held above the cavity portion provided in the silicon substrate while floating above the silicon substrate.

Further, in the acceleration sensor 100, the rectangular finger portion 27 is provided from the movable electrode 20 toward the space portion 40. The finger portion 27 has a length (in the Y-axis direction) of a, a width (in the X-axis direction) of b, and the same thickness (in the Z-axis direction) as the movable electrode 20. The interval (in the Y-axis direction) between the two connecting portions 23 is c. The width (in the X-axis direction) of the space portion 40 is a first space width Z1 at a central portion where the finger portion 27 is provided, and is a second space width Z2 at end portions on both sides of the central portion. W represents the width of the unit cell.

It is desirable that the finger portions 27 are arranged inside the two movable electrodes 20 at opposing positions. In FIG. 5, the end portions of the finger portions 27 are provided by being spaced apart from the connecting portion 23 in the Y-axis direction, thereby making it easier to etch a portion below the connecting portion 23. In an XY plane, it is desirable that the finger portions 27 have a rectangular shape, but may have other shapes such as a semicircular shape and the like as long as it is possible to control an etchant amount.

The finger portions 27 are integrally formed with the movable electrodes 20, and can be formed, for example, by patterning the silicon oxide film 2 into a shape as shown in FIG. 5 in the process of FIG. 3A.

Table 1 below shows results of etching when the finger width b is changed for electrode structures having groove widths X of 1.5 μm and 2.0 μm. Nos. 1 to 4 are directed to cases where the groove width X is 1.5 μm, and Nos. 5 to 9 are directed to cases where the groove width X is 2.0 μm. Since the unit cell width W is constant for all samples, the width Y of the movable electrode 20 is 5.2 μm in Nos. 1 to 4, but is as narrow as 4.7 μm in Nos. 5 to 9. Z1 is an interval (first space width Z1) between the opposing finger portions 27, and S is an area of a region sandwiched by the opposing finger portions 27.

TABLE 1

| Unit: μm | X | Y | a | b | Y + b | Z1 | Z1/2 | S(a*Z1) | NG reason |
|---|---|---|---|---|---|---|---|---|---|
| No. 1 | 1.5 | 5.2 | 10.8 | 0 | 5.2 | 9.0 | 4.5 | 97.2 | Fragile |
| No. 2 | 1.5 | 5.2 | 10.8 | 0.3 | 5.5 | 8.4 | 4.2 | 90.72 | OK |
| No. 3 | 1.5 | 5.2 | 10.8 | 0.6 | 5.8 | 7.8 | 3.9 | 84.24 | OK |
| No. 4 | 1.5 | 5.2 | 10.8 | 0.9 | 6.1 | 7.2 | 3.6 | 77.76 | Not |
| | | | | | | | | | releasable |
| No. 5 | 2.0 | 4.7 | 10.8 | 0 | 4.7 | 9.0 | 4.0 | 97.2 | OK |
| No. 6 | 2.0 | 4.7 | 10.8 | 0.5 | 5.2 | 8.0 | 4.0 | 86.4 | OK |
| No. 7 | 2.0 | 4.7 | 10.8 | 0.8 | 5.5 | 7.4 | 3.7 | 79.92 | OK |
| No. 8 | 2.0 | 4.7 | 10.8 | 1.1 | 5.8 | 6.8 | 3.4 | 73.44 | OK |
| No. 9 | 2.0 | 4.7 | 10.8 | 1.4 | 6.1 | 6.2 | 3.1 | 66.96 | Not |
| | | | | | | | | | releasable |

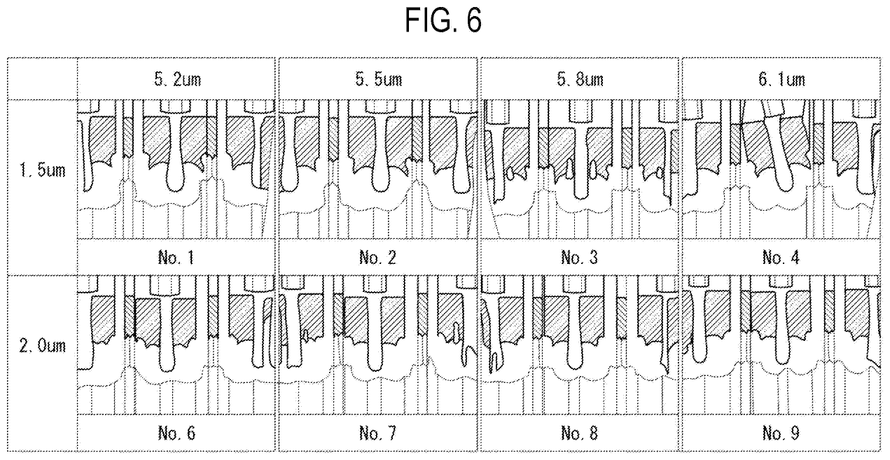

FIG. 6 is a schematic diagram showing etching results for the electrodes shown in Table 1, and the numbers (No. 1, etc.) in FIG. 6 correspond to the numbers in Table 1. For the etching, the etching conditions of the above-described electrode manufacturing processes 1 to 6 were used. When the groove width X is 1.5 μm, the width Y of the movable electrode 20 is 5.2 μm (constant). The finger width b was changed to 0 μm, 0.3 μm, 0.6 μm, and 0.9 μm. The combined width Y+b of the movable electrode 20 and the finger portion 27 is 5.2 μm (No. 1), 5.5 μm (No. 2), 5.8 μm (No. 3), and 6.1 μm (No. 4).

On the other hand, when the groove width X is 2.0 μm, the width Y of the movable electrode 20 is 4.7 μm (constant). The finger width b was changed to 0 μm, 0.5 μm, 0.8 μm, 1.1 μm, and 1.4 μm. The combined width Y+b of the movable electrode 20 and the finger portion 27 is 4.7 μm (No. 5), 5.2 μm (No. 6), 5.5 μm (No. 7), 5.8 μm (No. 8), and 6.1 μm (No. 9).

As can be seen from the schematic diagram of FIG. 6, when the groove width X is 1.5 μm and 2.0 μm, and Y+b is 5.5 μm and 5.8 μm (No. 2, No. 3, No. 7, and No. 8), good etching is achieved. When the width b of the finger portion 27 is increased such that Y+b is 6.1 μm, the etching becomes insufficient at the groove width X of both 1.5 μm (No. 4) and 2.0 μm (No. 9), and it becomes such that the movable electrode 20 is not able to be released from the silicon substrate 1 (Not releasable). On the other hand, when the width b of the finger portion 27 is reduced such that Y+b is 5.2 μm, it has a structure having the groove width X of 1.5 μm (No. 1) which was over-etched and a fragile protrusion remains below the fixed electrode 10 (Fragile).

Table 2 summarizes results of FIG. 1 and shows the dimensions for which good etching results were obtained.

TABLE 2

| X | Y + b | Z1 | Z1/X |
|---|---|---|---|
| 1.5 | 5.5 | 7.4 | 4.9 |
| 1.5 | 5.8 | 6.8 | 4.5 |
| 2.0 | 5.5 | 7.4 | 3.7 |
| 2.0 | 5.6 | 6.8 | 3.4 |

Thus, in the electrode structure in which the groove width X is narrowed to 2.0 μm or less, for example, 2.0 μm or 1.5 μm, a balance between an amount of the etchant entering from the groove portion 30 and an amount of the etchant entering from the space portion 40 can be adjusted well by setting the first space width Z1 within the range of 6.8 μm to 7.4 μm, i.e., by setting a value of a ratio Z1/X between the first space width Z1 and the groove width X in the range of 3.4 to 4.9. This makes it possible to obtain good electrode etching results.

Considering the mechanism of etching, in the electrode structure of FIG. 5, the etchant that contributes to the etching of the pair of fixed electrode 10 and movable electrode 20 is the etchant supplied from the half area (width: Z1/2) of the space portion 40 and one groove portion 30 (width: X). In the etching explanatory diagram of FIG. 5 (lower right), the white portion is a region to which the etchant is supplied, the hatched portion is a mask region, and the total length is ½ of the unit cell width W (hereinafter referred to as “half cell width”). As the groove width X of the groove portion 30 becomes smaller, it becomes more difficult to balance the etchants supplied from the two white portions.

First, a case where the groove width X of the groove portion 30 is relatively large, such as 2.0 μm or more and 2.8 μm or less, is considered. In this case, even when b=0 μm (no finger portion) as in No. 5 of Table 1, good etching is achieved. On the other hand, when b=1.4 μm as in No. 9, the etching is no good (NG). That is, when the ratio of the groove width X to the half cell width (W/2) of 11.2 μm is 0.18 (2.0 μm/11.2 μm) to 0.25 (2.8 μm/11.2 μm), the ratio occupied by the width b of the finger portion 27 is 0 (0 μm/11.2 μm) or more and less than 0.125 (1.4 μm/11.2 μm). Thus, good etching can be achieved.

On the other hand, when the groove width X of the groove portion 30 is as small as 1.5 μm or more and less than 2.0 μm, the etching is good within the range of No. 2 to No. 3 of Table 1, that is, within the range of b from 0.3 μm to 0.6 μm, and otherwise the etching is NG in No. 1 and No. 4. That is, when the ratio of the groove width X to the half cell width (W/2) of 11.2 μm is 0.13 (1.5 μm/11.2 μm) to 0.18 (2.0 μm/11.2 μm), the ratio occupied by the width b of the finger portion is 0.027 (0.3 μm/11.2 μm) or more and 0.054 (1.4 μm/11.2 μm) or less. Thus, good etching can be achieved.

In this example, the ratio of the finger width b to the half cell width (W/2) indicates a range in which the etching is good. At the similar ratio of the finger area (a×b) to the half of the area of the space (S/2), the etching becomes good. Therefore, even if the shape of the finger portion 27 is not rectangular, good etching can be achieved as long as the area satisfies a predetermined ratio. For example, the finger portion 27 may be semi-circular, wave-shaped, or the like.

As described above, in the MEMS sensor according to the embodiment of the present disclosure, for example, by controlling the supply amount of the etchant by providing the finger portion on the movable electrode, it is possible to provide an MEMS sensor, particularly a capacitive acceleration sensor, with high sensitivity and easy manufacturing.

The MEMS sensor having an electrode structure according to the present disclosure can be applied to a small acceleration sensor or the like.

According to the present disclosure in some embodiments, it is possible to provide an MEMS sensor with high sensitivity and easy manufacturing by adjusting the first space width Z1 of the space portion and the balance between the first space width Z1 and the groove width X of the groove portion.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A MEMS sensor, comprising:
a pair of movable electrodes arranged to be parallel to each other with a space portion interposed between the pair of movable electrodes above a cavity portion provided in a substrate; and
a fixed electrode arranged to be parallel to the pair of movable electrodes with a groove portion interposed between the fixed electrode and the pair of movable electrodes on an opposite side of the space portion with respect to the pair of movable electrodes,
wherein the space portion includes a central portion having a first space width and end portions having a second space width, and
wherein the first space width is shorter than the second space width.

2. The MEMS sensor of claim 1, wherein the first space width of the space portion and a groove width of the groove portion satisfy a following formula (1):
3.4≤(Z1/X)≤4.9 (1)
where Z1 is the first space width and X is the groove width.

3. The MEMS sensor of claim 1, wherein the pair of movable electrodes include finger portions on a side of the space portion, respectively, and
wherein the first space width is an interval between the finger portions.

4. A MEMS sensor, comprising:
a pair of movable electrodes arranged to be parallel to each other with a space portion interposed between the pair of movable electrodes above a cavity portion provided in a substrate; and
a fixed electrode arranged to be parallel to the pair of movable electrodes with a groove portion interposed between the fixed electrode and the pair of movable electrodes on an opposite side of the space portion with respect to the pair of movable electrodes,
wherein the pair of movable electrodes includes finger portions on a side of the space portion, respectively, and
wherein, when a groove width of the groove portion is 2.0 μm or more and 2.8 μm or less, a following formula (2) is satisfied:
0≤b/((Z1/2)+(Y+b)+X)<0.125 (2)
where Z1 is an interval between the finger portions, Y is a width of each of the pair of movable electrodes, b is a width of the finger portions, and X is the groove width.

5. A MEMS sensor, comprising:
a pair of movable electrodes arranged to be parallel to each other with a space portion interposed between the pair of movable electrodes above a cavity portion provided in a substrate; and
a fixed electrode arranged to be parallel to the pair of movable electrodes with a groove portion interposed between the fixed electrode and the pair of movable electrodes on an opposite side of the space portion with respect to the pair of movable electrodes,
wherein the pair of movable electrodes includes finger portions on a side of the space portion, and
wherein, when a groove width of the groove portion is 1.5 μm or more and less than 2.0 μm, a following formula (3) is satisfied:
0.027≤b/((Z1/2)+(Y+b)+X)≤0.054 (3)
where Z1 is an interval between the finger portions, Y is a width of each of the pair of movable electrodes, b is a width of the finger portions, and X is the groove width.

6. The MEMS sensor of claim 4, wherein the finger portions are rectangular protrusions.
